(19) United States
(12) Patent Application Publication
(10) Pub. No.: US 2011/0048508 A1
(43) Pub. Date: Mar. 3, 2011

(54) Doping of Carbon Nanotube Films for the Fabrication of Transparent Electrodes

(75) Inventors: Ali Afzali-Ardakani, Yorktown Heights, NY (US); Goerge S. Tulevski, Yorktown Heights, NY (US)

(73) Assignee: International Business Machines Corporation, Armonk, NY (US)

(21) Appl. No.: 12/548,250

(22) Filed: Aug. 26, 2009

(51) Int. Cl. H01L 31/0224; B05D 5/12

(52) U.S. Cl. 136/252; 427/113; 427/74; 977/742

(57) ABSTRACT

Techniques for increasing conductivity of carbon nanotube films are provided. In one aspect, a method for increasing conductivity of a carbon nanotube film includes the following steps. The carbon nanotube film is formed from a mixture of metallic and semiconducting carbon nanotubes. The carbon nanotubes are exposed to a solution comprising a one-electron oxidant configured to dope the semiconducting carbon nanotubes to increase a conductivity thereof, thereby increasing the overall conductivity of the film. The step of forming the carbon nanotube film can be performed prior to the step of exposing the carbon nanotubes to the one-electron oxidant solution. Alternatively, the step of exposing the carbon nanotubes to the one-electron oxidant solution can be performed prior to the step of forming the carbon nanotube film. A method of fabricating a transparent electrode on a photovoltaic device from a carbon nanotube film is also provided.

### FIELD OF THE INVENTION

The present invention relates to carbon nanotubes, and more particularly, to techniques for increasing the conductivity of carbon nanotube films.

### BACKGROUND OF THE INVENTION

A conductive transparent electrode is an integral component of a photovoltaic cell. Indium tin oxide (ITO) is currently the most commonly used transparent electrode material. Although ITO offers excellent optical and electrical properties, the fabrication of an ITO electrode involves costly vacuum deposition techniques. ITO (and other metal oxides) also suffer from being brittle, and thus are incompatible with flexible substrates. Further, with the increasing costs of mined metals, ITO is becoming a less economically viable solution for large scale photovoltaic cell production.

Carbon nanotubes are considered a leading candidate to replace ITO as the transparent electrode material in photovoltaic devices. Namely, carbon nanotubes can be solution processed, which can significantly reduce the cost of photovoltaic device fabrication, and allows for compatibility with virtually any substrate.

As-grown carbon nanotubes consist of about one-third metallic and about two-thirds semiconducting carbon nanotubes. Thus, the minimum sheet resistance achievable is limited, in part, by the presence of the semiconducting carbon nanotubes. Attempts to improve the optoelectronic properties of carbon nanotubes have been made. For example, in Williams et al., “Boron-Doped Carbon Nanotube Coating for Transparent, Conducting, Flexible Photonic Devices,” Applied Physics Letters 91, 143116 (2007) (hereinafter “Williams”) boron doping is used to achieve a certain sheet resistance in single-walled carbon nanotubes. However, the ultimate sheet resistances obtained in Williams were very high, too high in fact to be technologically relevant. Also, in R. Jackson et al., “Stability of Doped Transparent Carbon Nanotube Electrodes,” Adv. Funct. Mater. 18, 2548-2554 (2008), single-walled carbon nanotube films are doped via chemical treatment with HNO₃ and SOCL₂ to reduce sheet resistance. The doping enhancements, however, showed limited stability in air and under thermal loading.

Therefore, improved techniques for reducing the sheet resistance of carbon nanotubes would be desirable.

### SUMMARY OF THE INVENTION

The present invention provides techniques for increasing conductivity of carbon nanotube films. In one aspect of the invention, a method for increasing conductivity of a carbon nanotube film includes the following steps. The carbon nanotube film is formed from a mixture of metallic and semiconducting carbon nanotubes. The carbon nanotubes are exposed to a solution comprising a one-electron oxidant configured to dope the semiconducting carbon nanotubes to increase a conductivity thereof, thereby increasing the overall conductivity of the film. The step of forming the carbon nanotube film can be performed prior to the step of exposing the carbon nanotubes to the one-electron oxidant solution. Alternatively, the step of exposing the carbon nanotubes to the one-electron oxidant solution can be performed prior to the step of forming the carbon nanotube film.

In another aspect of the invention, a method of fabricating a transparent electrode on a photovoltaic device from a carbon nanotube film is provided. The method includes the following steps. The carbon nanotube film is formed from a mixture of metallic and semiconducting carbon nanotubes on a surface of the photovoltaic device. The carbon nanotubes are exposed to a solution comprising a one-electron oxidant configured to dope the semiconducting carbon nanotubes to increase a conductivity thereof, thereby increasing the overall conductivity of the film. The step of forming the carbon nanotube film can be performed prior to the step of exposing the carbon nanotubes to the one-electron oxidant solution. Alternatively, the step of exposing the carbon nanotubes to the one-electron oxidant solution can be performed prior to the step of forming the carbon nanotube film.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary methodology for increasing conductivity of a carbon nanotube film according to an embodiment of the present invention;

FIG. 2 is a graph illustrating carbon nanotube films with their corresponding sheet resistance and transparencies both for doped and undoped films according to an embodiment of the present invention; and

FIGS. 3A and 3B are diagrams illustrating an exemplary methodology for fabricating a transparent electrode on a photovoltaic device from a carbon nanotube film according to an embodiment of the present invention.

### DETAILED DESCRIPTION OF PREFERRED EMBODIMENTS

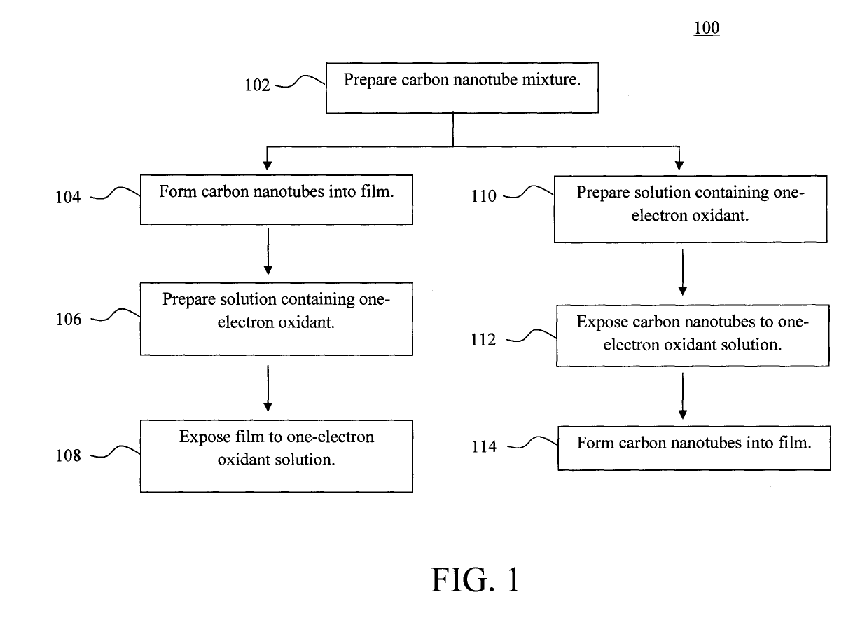

FIG. 1 is a diagram illustrating exemplary methodology 100 for increasing conductivity of a carbon nanotube film. In step 102, a carbon nanotube mixture is prepared by dispersing powder carbon nanotubes in a liquid medium such as water (with a surfactant), an appropriate organic solvent(s) such as dimethylformamide (DMF), N-Methyl-2-pyrrolidone (NMP) and/or dichloroethylene (DCE) or by functionalizing the carbon nanotubes with groups that aid in dispersion and then dispersing them in, e.g., an organic solvent. The mixture can then be purified by high speed centrifugation, either with or without a step gradient.

As highlighted above, as-grown carbon nanotubes include both metallic and semiconducting carbon nanotubes. When the carbon nanotubes are used to form films, such as transparent conductive films for photovoltaic applications (see below), the presence of the semiconducting carbon nanotubes in the film can limit a minimum sheet resistance attainable. As known by those of skill in the art, sheet resistance and conductivity are inversely related to one another, i.e., as sheet resistance decreases conductivity increases, and vice-a-versa. Advantageously, the present teachings provide techniques for further reducing the sheet resistance/increasing the conductivity in such films.

In step 104, the carbon nanotubes are formed into a film. According to an exemplary embodiment, the film is formed by depositing the carbon nanotube mixture onto a given substrate, e.g., a photovoltaic device, using spin-coating, dip-coating and/or spray coating. The term “substrate” is used to generally refer to any suitable substrate on which one would want to deposit a carbon nanotube film. By way of example only, the substrate can be a photovoltaic device, on which the carbon nanotube film is deposited as a transparent electrode material. The film can also be formed via vacuum filtration followed by transfer onto the substrate. According to an exemplary embodiment, the carbon nanotube film is formed on a mixed cellulose ester filter paper via vacuum filtration. The filter paper, with the carbon nanotube film, can then be pressed onto a suitable substrate. The filter paper is then dissolved in acetone or acetone vapor, leaving the carbon nanotube film behind.

The carbon nanotubes can be deposited as a “neat” solution or mixed with various polymers, such as polyanaline, poly(3,4-ethylenedioxythiophene)poly(styrenesulfonate) (PEDOT:PSS) and polythiophene, to improve the film quality. Namely, the polymers can increase the contact area between carbon nanotubes, fill voids in the film with conducting materials as opposed to air and allow for increased ease in film fabrication by increasing the solution viscosity.

In step 106, a solution is prepared containing a one-electron oxidant in a solvent. According to an exemplary embodiment, the one-electron oxidant is triethyloxonium hexachloroantimonate. Suitable solvents include, but are not limited to one or more of methylene chloride, DMF, chloroform and acetone. A typical preparation involves adding 10 milligrams (mg) of the one-electron oxidant to 10 milliliters (ml) of solvent. The solution is stirred or sonicated until the one-electron oxidant completely dissolves into the solution.

In step 108, the film is exposed to the one-electron oxidant solution. According to an exemplary embodiment, the film is soaked in the one-electron oxidant solution for a duration of at least about 10 minutes, e.g., for a duration of about 30 minutes. By way of example only, if the film is being used as a transparent electrode material for a photovoltaic device, then the film can first be deposited on the device and the device with the film exposed to (e.g., soaked in) the one-electron oxidant solution. After the film is exposed and soaked for a proper length of time, it is simply removed from solution and rinsed with an appropriate solvent, such as acetone. Exposing the film to the one-electron oxidant solution serves to dope the semiconducting carbon nanotubes in the film, thereby reducing the overall sheet resistance of the film. It is believed that the one-electron oxidant dopes the semiconducting carbon nanotubes to a high-conductivity (metallic) state. Initially only 33 percent (%) of the carbon nanotubes are in a high conductivity state as only one-third are metallic. By doping, the other 66% are converted to a high conductivity state, thus reducing the resistance/increasing the conductivity of the entire film.

The dopant reduces the sheet resistance by a factor of from about two to about four (see below). Further, advantageously, the doped film has enhanced stability as compared with other doping methods (see above). For example, doped films prepared according to the present techniques remain stable even after several months. In fact, the process should last indefinitely especially if, e.g., the photovoltaic device containing the present doped film is encapsulated in some sort of polymer. The present method is more stable because the metal salts form a charge transfer complex with the carbon nanotubes that is difficult to reverse.

Alternatively, the carbon nanotubes can be doped in solution, prior to forming the film, and achieve the same results. Namely, in step 110, the one-electron oxidant solution, e.g., triethyloxonium hexachloroantimonate in methylene chloride, DMF, chloroform and/or acetone, is prepared. The process for preparing the one-electron oxidant solution was described in detail above.

In step 112, the one-electron oxidant solution is added to the carbon nanotubes dispersed in a liquid medium, see step 102 described above. Exposing the carbon nanotubes to the one-electron oxidant solution serves to dope the semiconducting carbon nanotubes.

In step 114, the carbon nanotubes are formed into a film in which the carbon nanotubes are already doped. Exemplary processes for forming a carbon nanotube film were described in detail above.

Advantageously, the present techniques are completely solution based, which has enormous cost advantages in photovoltaic fabrication. Namely, the raw materials used in the present process are cheaper (carbon versus indium (see above)), the process is entirely from solution and there is no need for expensive vacuum deposition techniques (see above). Further, the doping procedure is independent of the type of carbon nanotubes used or the method of film deposition used.

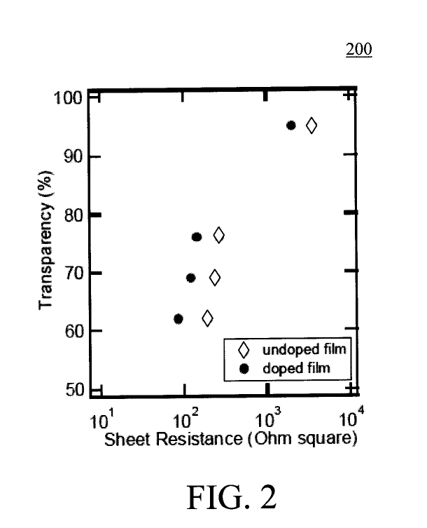

FIG. 2 is a graph 200 illustrating carbon nanotube films with their corresponding sheet resistance and transparencies both for doped and undoped films. The doped samples were prepared according to the techniques presented above. In graph 200, sheet resistance (measured in Ohm square) is plotted on the x-axis and transparency (measured in %) is plotted on the y-axis. As shown in graph 200, the sheet resistance consistently decreased, through doping, by at least a factor of two for all of the films.

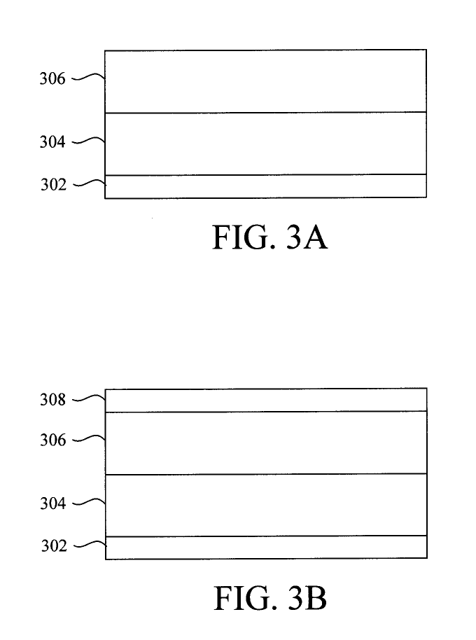

FIGS. 3A and 3B are diagrams illustrating an exemplary methodology for fabricating a transparent electrode on a photovoltaic device from a carbon nanotube film. A generic photovoltaic device is shown in FIG. 3A. The photovoltaic device includes a bottom electrode 302, a first photoactive layer 304 and a second photoactive layer 306. By way of example only, the first and second photoactive layers can be doped so as to have opposite polarities from one another, e.g., one is doped with a p-type dopant and the other is doped with an n-type dopant. In this example, a p-n junction would be formed between the two photoactive layers. Such a generic photovoltaic device would be apparent to one of skill in the art and thus is not described further herein. Further, as would be apparent to one of skill in the art, there are a multitude of different photovoltaic device configurations possible, and the configuration shown in FIG. 3A is provided merely to illustrate the present techniques for fabricating a transparent electrode on the photovoltaic device from a carbon nanotube film having increased conductivity.

As shown in FIG. 3B, carbon nanotube film 308 which will serve as the transparent electrode is formed on a surface of the photovoltaic device, in this example on a surface of second photoactive layer 306. As above, the carbon nanotube film is formed from a mixture of metallic and semiconducting carbon nanotubes. As described above, the conductivity of the carbon nanotube film can be increased by exposing the carbon nanotubes to a solution containing a one-electron oxidant (e.g., triethyloxonium hexachloroantimonate) either as a mixture (i.e., prior to forming the film) or as a film, to dope the semiconducting carbon nanotubes. By way of example only, the photovoltaic device with the film formed thereon can be exposed to (e.g., soaked in) the one-electron oxidant solution or the one-electron oxidant can be added to the mixture.

As highlighted above, the carbon nanotube film 308 can be formed on the surface of the photovoltaic device in a number of different ways. By way of example only, carbon nanotube film 308 can be formed by depositing the carbon nanotube mixture onto the surface of the photovoltaic device using spin-coating, dip-coating and/or spray coating. Alternatively, carbon nanotube film 308 can first be formed on a filter paper using vacuum filtration and then transferred from the filter paper to the surface of the photovoltaic device. See above.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method for increasing conductivity of a carbon nanotube film, comprising the steps of:
forming the carbon nanotube film from a mixture of metallic and semiconducting carbon nanotubes; and
exposing the carbon nanotubes to a solution comprising a one-electron oxidant configured to dope the semiconducting carbon nanotubes to increase a conductivity thereof, thereby increasing the overall conductivity of the film.

2. The method of claim 1, wherein the step of forming the carbon nanotube film is performed prior to the step of exposing the carbon nanotubes to the one-electron oxidant solution.

3. The method of claim 1, wherein the step of exposing the carbon nanotubes to the one-electron oxidant solution is performed prior to the step of forming the carbon nanotube film.

4. The method of claim 1, further comprising the steps of:
preparing the solution of the one-electron oxidant in a solvent;

5. The method of claim 4, wherein the one-electron oxidant comprises triethyloxonium hexachloroantimonate.

6. The method of claim 4, wherein the solvent comprises one or more of methylene chloride, dimethylformamide, chloroform and acetone.

7. The method of claim 1, wherein the step of exposing the carbon nanotubes to the one-electron oxidant in solution further comprises the step of:
soaking the film in the solution.

8. The method of claim 7, wherein the film is soaked in the solution for a duration of about 30 minutes.

9. The method of claim 1, further comprising the step of:
preparing a mixture of the metallic and semiconducting carbon nanotubes dispersed in a liquid medium.

10. The method of claim 9, further comprising the step of:
purifying the mixture.

11. The method of claim 10, wherein the mixture is purified using centrifugation.

12. The method of claim 9, wherein the step of forming the carbon nanotube film further comprises the step of:
depositing the mixture onto a substrate.

13. The method of claim 12, wherein the mixture is deposited on the substrate using one or more of spin-coating, dip-coating or spray coating.

14. The method of claim 12, wherein the substrate comprises at least a portion of a photovoltaic device.

15. A carbon nanotube film having increased conductivity prepared by the method of claim 1.

16. A method of fabricating a transparent electrode on a photovoltaic device from a carbon nanotube film, comprising the steps of:
forming the carbon nanotube film from a mixture of metallic and semiconducting carbon nanotubes on a surface of the photovoltaic device; and
exposing the carbon nanotubes to a solution comprising a one-electron oxidant configured to dope the semiconducting carbon nanotubes to increase a conductivity thereof, thereby increasing the overall conductivity of the film.

17. The method of claim 16, wherein the step of forming the carbon nanotube film is performed prior to the step of exposing the carbon nanotubes to the one-electron oxidant solution.

18. The method of claim 16, wherein the step of exposing the carbon nanotubes to the one-electron oxidant solution is performed prior to the step of forming the carbon nanotube film.

19. The method of claim 16, wherein the step of forming the carbon nanotube film further comprises the step of:
depositing the carbon nanotube mixture onto the surface of the photovoltaic device using one or more of spin-coating, dip-coating and spray coating.

20. The method of claim 16, wherein the step of forming the carbon nanotube film further comprises the steps of:
forming the carbon nanotube film on filter paper using vacuum filtration; and
transferring the carbon nanotube film from the filter paper to the surface of the photovoltaic device.
